(19) United States
(12) Patent Application Publication
(10) Pub. No.: US 2004/0253374 A1
(43) Pub. Date: Dec. 16, 2004

(54) Treatment of carbon nano-structure using fluidization

(76) Inventors: Kyeong Taek Jung, Suwon-si (KR); Myung Soo Kim, Suwon-si (KR); Kwan Goo Jeon, Jeonju-si (KR); Young Hee Lee, Suwon-si (KR)

Correspondence Address: David A. Einhorn, Esq., Anderson Kill & Olick, P.C., 1251 Avenue of the Americas, New York, NY, 10020, US

(21) Appl. No.: 10/830,914

(22) Filed: Apr. 23, 2004

(30) Foreign Application Priority Data
Apr. 23, 2003 (KR) 2003-0025733
Apr. 30, 2003 (KR) 2003-0027453

(51) Int. Cl. C23C 16/26

(52) U.S. Cl. 427/213; 427/249.1

(57) ABSTRACT

The present invention relates to an efficient and simple method for treating a carbon nano-structure, comprising fluidizing the carbon nano-structure in a reactor using a carrier gas introduced into the reactor; and then introducing a reactive gas in the reactor to contact the fluidized carbon nano-structure. In accordance with the inventive method, carbon nano-structures can be effectively purified, uniformly surface-treated and easily employable in the post-process, e.g., in the production of a composite comprising same.

### FIELD OF THE INVENTION

The present invention relates to a method for treating a carbon nano-structure, particularly to a method for purifying or surface-treating it in a fluidized condition.

### BACKGROUND OF THE INVENTION

Carbon nano-structures such as carbon nanofiber, fullerene, cabon nanotube and carbon nanohorn have been employed in various industries. Crude carbon nano-structures synthesized by various methods generally contain impurities such as non-crystalline carbon, catalyst used and other impurities. To remove such impurities, conventional methods have been used, e.g., dipping in a strong acid solution, followed by heat-treatment under an oxygen atmosphere. However, such a method requires a long dipping time due to inefficient contact between the crude carbon structures and the acid, and causes the agglomeration of purified carbon nano-structures.

To overcome the above disadvantages, Korean Patent No. 372331 suggested gas phase purification of the crude carbon nano-structures using a gaseous acid. However, this method still has the problem of long purification time.

Carbon nano-structures have also been employed as a filler, in combination with a polymer matrix resin, to obtain an organic-inorganic composite. To enhance the interfacial property of the carbon nano-structure filler, the carbon nano-structure is subjected to a chemical or electrochemical surface-treatment prior to mixing with the matrix. For instance, Korean Patent Publication No. 2002-82816 discloses a method of treating the surface of carbon nano-structures with an alkaline transition metal using an electric decomposition; Korean Patent No. 372307, and Korean Patent Publication Nos. 2002-54883 and 2002-39998, methods of preparing functional carbon nano-structures having thiol substituents by treating carbon nano-structures successively with ultrasonic waves, an acid and thiourea; and Korean Patent Publication No. 2001-85825, a method of synthesizing a fluorinated carbon nanotube by reacting a carbon nanotube with a gaseous fluorine.

In these above surface-treatment techniques, however, carbon structures are brought into contact with the reactive material in a manner which is inefficient in terms of contactability, and generate agglomerates of the carbon structures.

### SUMMARY OF THE INVENTION

Accordingly, it is an object of the present invention to provide an efficient and simple method for purifying or surface-treating a carbon nano-structure having good dispersability.

In accordance with the present invention, there is provided a method for treating a carbon nano-structure, which comprises:

(A) fluidizing the carbon nano-structure in a reactor using a carrier gas introduced into the reactor; and

(B) separately introducing a reactive gas in the reactor to contact the fluidized carbon nano-structure.

### BRIEF DESCRIPTION OF THE DRAWINGS

The above and other objects and features of the present invention will become apparent from the following description of the invention, when taken in conjunction with the accompanying drawings, which respectively show:

FIG. 1: a schematic view of the apparatus for the synthesis, purification and surface-treatment of carbon nano-structures, used in Example 1 according to the present invention;

FIG. 2: a schematic view of the apparatus for the purification and surface-treatment of carbon nano-structures previously synthesized, used in Example 2 according to the present invention;

FIG. 3: a scanning electronic microscopic photograph of the carbon nano-structures prepared in Example 1;

FIG. 4A: the particle distribution of the dispersion of untreated carbon nano-structures;

FIG. 4B: the particle distribution of the dispersion of the carbon nano-structures purified and surface-treated according to the present invention;

FIG. 5: Raman spectra of the carbon nano-structures purified in Example 2;

FIG. 6: X-ray photoelectron spectra of the nano-structures before and after the treatment with the fluorinating gas, and after the heat-treatment; and

FIGS. 7A and 7B: scanning electronic microscopic photographs of carbon nano-structures, before and after the purification according to Example 3.

### DETAILED DESCRIPTION OF THE INVENTION

The inventive method is characterized in that carbon nano-structures are purified and surface-treated in a fluidized manner.

I. Formation of Fluidization Region

In accordance with the present invention, a carbon nano-structure is treated with a reactive gas in a fluidization region which is formed in the center part of a reactor by the action of a carrier gas flow.

Examples of the carrier gas which may be used to form a fluidization region in the invention include air, nitrogen (N₂), an inert gas such as helium (He) or argon (Ar) and a mixture thereof.

The carrier gas is sprayed from a nozzle by a ultrasonic jet method. The tip portion of the nozzle may be provided with a ceramic filter or mesh having a circular, star-shaped or triangular hole of several ten to several hundred μm diameter, which is capable of directing the carrier gas flow to the center region of the reactor.

The carrier gas may be introduced from the bottom of the reactor, or simultaneously from the top and bottom.

In the present invention, the flow rate of the carrier gas fed from the bottom of the reactor is preferably in the range of 10 to 5,000 cc/min to keep carbon nano-structures fluidized at the fluidization region.

When the carrier gas is simultaneously introduced from the top and the bottom of the reactor to form the fluidization region, the flow rate of the carrier gas introduced at the bottom ranges from 100 to 5,000 cc/min and the carrier gas introduced downward from the top ranges from 100 to 1,000 cc/min. The downward flow prevents a reactive gas from escaping from the reactor and assists the fluidization of the carbon nano-structures.

In the present invention, the carbon nanosturcutre to be treated may be those obtained from a conventional method, for example, arc method, chemical vapor deposition, pyrolysis, etc., or may be in situ synthesized and successively treated by the fluidization method of the present invention. Particularly, the in situ synthesis of the carbon nano-structure using fluidization method is preferred in case of mass production.

Accordingly, the present invention will be described on the basis of in situ synthesis of a carbon nano-structure using fluidization, which is, however, not intended to limit the scopes of the present invention.

II. Synthesis of Carbon Nano-Structure Using Fluidization

A carbon nano-structure may be synthesized by introducing a carrier gas so as to form a fluidization region, and then a carbon source and a reactive catalyst in the upward direction in a reactor and reacting the carbon source and the reactive catalyst in the fluidization region.

Examples of the carbon source include a gaseous carbon source such as acetylene (C₂H₂), ethylene (C₂H₄), methane (CH₄), benzene (C₆H₆), xylene (C₆H₄(CH₃)₂), carbon monoxide (CO), ethane (C₂H₆) or propane (C₃H₈), propene (C₃H₆); and a liquid carbon source such as an alcohol, e.g., methanol (CH₃OH) or ethanol (C₂H₅OH). The liquid carbon source material may be evaporized by using a nozzle equipped with a heating wire wrapped around its inlet or using a furnace for pretreatment maintained at a temperature of 200 to 400 □ before being introduced to the fluidization region. The carbon source may be suitably introduced at a flow rate of 10 to 5,000 cc/min.

Also, examples of the catalyst used in the synthesis of the carbon nano-structure include at least one selected from Group IA metals, e.g., Li and K; Group IIA metals, e.g., Ma and Ca; Group IIIA metals, e.g., Sc, Y, La and Ac; Group IVA metals, e.g., Ti, Zr and Hf; Group VA metals, e.g., V and Nb; Group VIA metals, e.g., Cr, Mo and W; Group VIIA metals, e.g., Mn; Group VIIIA metals, e.g., Fe, Co, Ni, Ru, Rh, Pd, Os, Ir and Pt; Group IB metals, e.g., Cu; Group IIB metals, e.g., Zn; Group IIIB metals, e.g., B, Al, Ga and In; Group IVB metals, e.g., Si, Ge and Sn; Group VB metals, e.g., As and Sb; an alloy thereof; AN oxide, nitride, carbide, sulfide, chloride, sulfate or nitrate thereof and a mixture thereof; or an organic composite thereof, e.g., ferrocene (FeC₁₀H₁₀), molybdenum hexacarbonyl (Mo(CO)₆), cyclopentadienyl cobalt dicarbonyl ((C₅H₅)Co(CO)₂), nickel dimethylglyoxime, iron chloride (FeCl₃), and iron acetate (Fe(OH)(CH₃COO)₂).

The reactive catalyst is preferably previously heat-treated for activation before introduced to the fluidization region.

Also, in order to prevent catalyst particles from agglomerating at the entrance of a hot reactor, the catalyst is preferably employed together with an etching gas such as ammonia or hydrogen. A mixture of the catalyst and etching gas is preferably introduced at a flow rate of 10 to 3,000 cc/min.

The nozzle for injecting the catalyst and the carbon source is preferably provided with a ceramic filter or mesh having holes of several ten nm to several ten μm diameter.

The reaction of catalyst particles with a carbon source gas may be conducted at a temperature of 400 to 1,500° C.

In the synthesis of a carbon nano-structure using fluidization, the carrier gas injected from the bottom of a reactor can prevent the grown carbon nano-structure from falling in the gravitational direction, and allows the reaction of carbon source with relatively small catalyst particles, to provide the carbon nano-structures of nano sizes. The reaction of the carbon source and the catalyst may be conducted for a time of 10 seconds to 5 hours.

The synthesized carbon nano-structure may be collected in a simple and continuous manner by stopping the introduction of the carrier gas at the top of the reactor and increasing the flow rate of the carrier gas introduced at the bottom of the reactor to discharge carbon nano-structures from into the top of the reactor. The discharged carbon nano-structures can be collected in a collector.

In accordance with the present invention, the carbon nano-structure thus synthesized may be post-treated in the same reactor used in the synthesis or in a separate reactor.

III. Treatment of Carbon Nano-Structure Using Fluidization

The carbon nano-structure synthesized may conventionally contain impurities such as amorphous carbon and metal, and thus it is required to purify or further surface treat according to the intended use purpose.

In accordance with the present invention, the crude carbon nano-structure powder is purified or surface-treated in a fluidized state. The purification and surface treatment may be conducted in a single reactor or at least two successive reactors and they may be independently or successively conducted.

In the present invention, the purification and surface treatment of carbon nano-structures may be conducted by contacting carbon nano-structure powders with a reactive gas in a fluidization region of a reactor formed by introducing a carrier gas into the reactor. The reactive gas and the carrier gas may flow in various directions, for example, in upwardly or downwardly.

In the inventive method, a uniform gas flow forms around carbon nano-structure powders, making it possible it bring all carbon nano-structure powders into uniform contact with the carrier gas without channeling which often occurs in a fixed bed reactor.

The efficiency of purification and surface treatment may be enhanced by raising the operating temperature within a range which does not influence the chemical properties of carbon nano-structures. The operating temperature may be controlled using an electric furnace, a radio frequency or microwave plasma, an arc plasma, a laser or a combination thereof.

The purification is conducted with an oxidative gas and/or an acidic gas as a reactive gas. When the oxidative gas is brought into contact with fluidized crude carbon nano-structure powders at a temperature of 200 to 1,000° C., the amorphous carbon present in the crude carbon nano-structure are oxidized and removed from the carbon nano-structure as COₓ. The acidic gas may be introduced into the reactor by a bubbling, spraying or atomizing method and contacted with the carbon nano-structure at 10 to 700° C. for 1 minute to 10 hours, to etch a metal component which may be incorporated from a catalyst used in the course of the carbon nano-structure synthesis.

Also, the oxidation by the oxidative gas and the etching by the acidic gas may be successively or simultaneously conducted in any order. Only one of the oxidation and the etching process may be conducted depending on the purification purpose.

Examples of the oxidative gas useful in the present invention include air, oxygen, carbon dioxide, hydrogen peroxide and a mixture thereof. Examples of the acidic gas useful in the present invention include hydrochloric acid, nitric acid, fluoric acid, sulfuric acid and a mixture thereof. In the present invention, the acidic gas may be used as is or in the form of a diluted acid solution. When a diluted acid solution is used, it may be circulated in a reactor using a carrier gas and then discharged from the bottom of the reactor to treat the carbon nano-structure.

In some cases, functional groups such as —OH or —COOH remain on the surface of the carbon nano-structure after purification. If such functional groups formed on the surface thereof are not necessary, the purified carbon nano-structure may be further heat-treated under an inert gas atmosphere such as nitrogen, argon or helium at 200 to 1,500° C. for 1 minute to 5 hours, preferably about 800° C. for about 1 hour, to remove the functional groups therefrom.

The purified carbon nano-structure may be collected from the top of the reactor by increasing the flow rate of the carrier gas introduced from the bottom of the reactor, and the collected carbon nano-structure may be preferably further purified by passing through a collecting classifier. Representative examples of the wind collecting classifier include a gravitational classifier, an inertial classifier, a centrifugal classifier and an advective collecting classifier and preferably an advective collecting classifier is used in the present invention. An advective collecting classifier has a collecting container divided into at least two parts each of which has an electric classifier for collecting particles to prevent the particles once entered in the container from escaping.

As mentioned above, the removal of the impurities present in carbon nano-structures may be continuously conducted in a high efficiency by the fluidization method of the present invention.

In the present invention, the carbon nano-structure may be treated with surface-treating agents one more time to form carbon nano-structures having defects or functional groups which may be favorably used in the production of e.g., an organic-inorganic composite.

Carbon nano-structures may be treated with a reactive gas as a preliminary surface-treating agent to form various functional groups on the surface of the carbon nano-structures. Examples of the preliminary surface-treating agent include ozone, nitrogen oxides (NOₓ), ammonia (NH₃), hydrogen cyanide (HCN), sulfur oxides (SO₂), chlorine (Cl₂), carbon dioxide (CO₂), hydrochloric acid (HCl), nitric acid (HNO₃), fluoric acid (HF), phosphoric acid (H₃PO₄), sulfuric acid, (H₂SO₄), hydrogen peroxide (H₂O₂), potassium permanganate (KMnO₄), chlorine dioxide (ClO₂), potassium iodate (KIO₃), pyridine, hydrogen sulfide (H₂S), nitrating agents, sulfonating agents or a mixture thereof.

The preliminary surface-treating agent may generate functional groups such as nitro (—NO₂), sulfone (—SO₃H), aldehyde (—CHO), carboxyl (—COOH), carbonyl (>CO), ether (—O—), hydroxyl (—OH), cyano (—CN), thiol (—SH), and phosphine (≡P) on the surface of the carbon nano-structure.

The surface treatment using the preliminary surface-treating agent may be conducted at 400 to 1,000° C.

In accordance with the present invention, a secondary surface-treating agent may provide carbon nano-structures having defects or functional groups to form secondary functional groups on the surface of the carbon nano-structure, which facilitates efficiency of the post treatment processes.

Examples of the secondary surface-treating agent which may be optionally used in the present invention include any surface-treating agent capable of reacting with the functional groups formed on the surface of the preliminary surface-treated carbon nano-structure, particularly silane-, titane-, borone-, and aluminium-based alkoxides and organocompounds; metal chlorides, nitrates, acetates or carbonates; coupling agents; vaporized metals; fluorinating gases; silating gases; phosphines; drug precursors capable of being introduced into a body; and mixtures thereof.

In accordance with the present invention, the surface-treating agent may be introduced in the form of a gas or micronized liquid drops and the liquid surface-treating agent may be introduced by a bubbling, spraying or atomizing method in to the fluidized region. Further, in another aspect of the present invention, the carbon nano-structure is surface-treated by circulating a diluted solution of a surface-treating agent into the reactor using a carrier gas, discharging the used solution form the bottom of the reactor, filtering the surface-treated carbon nano-structure and then drying and heat-treating the filtered nano-structure in the fluidization region using a carrier gas at a controlled temperature.

In the inventive method, the surface of the carbon nano-structure can be treated by bringing a surface-treating agent into contact with carbon nano-structures without causing the agglomeration of the treated carbon nano-structures, which can be further used in the production of a composite. That is, after the surface treatment is completed, the surface-treated carbon nano-structures may be moved to the outlet of the reactor by increasing the flow rate of the carrier gas introduced from the bottom of the reactor and the carbon nano-structures may be mixed with a matrix material to obtain a composite in a continuous manner.

Thus, in accordance with the present invention, as the carbon nano-structure may be continuously subjected to the synthesis, the purification, the surface treatment and the production of a composite and all these processes may be automatically conducted.

The present invention will be described in further detail by the following Examples, which are, however, not intended to limit the scopes of the present invention.

### EXAMPLE 1

### In Situ Synthesis, Purification and Surface-Treatment of Carbon Nano-Structures Using Fluidization

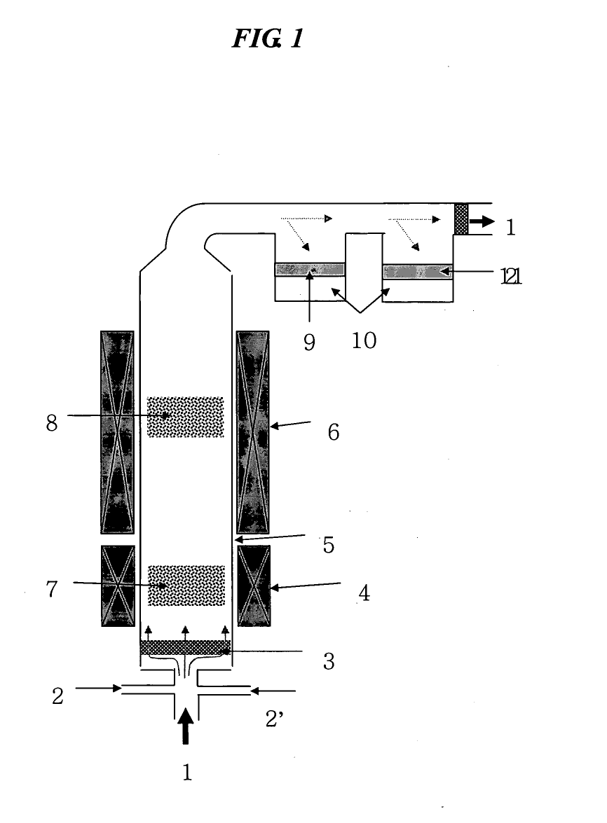

Carbon nano-structures were synthesized and in situ post-treated using a fluidization method in the apparatus shown in FIG. 1, as follows.

Step 1) Synthesis of Carbon Nano-Structures

A nitrogen carrier gas was introduced at a flow rate of 500 cc/min into quartz reactor (5) through inlet (1) equipped with ceramic filter (3), while pretreatment furnace block (3) of the reactor was maintained at 300° C. and electric furnace block (6) of the reactor was maintained at 800° C. After 10 minutes, ferrocene (FeC₁₀H₁₀), a catalyst for the synthesis of carbon nano-structures, was introduced into the reactor through inlet (2′) by bubbling a 0.01 wt % solution of ferrocene in benzene together with gaseous ammonia in an amount of 5% by volume of the ferrocene solution, at a flow rate of 200 cc/min, to be pre-treated at pretreatment region (7). After the catalyst was pretreated for 30 minutes in the pretreatment region (7), the nitrogen carrier gas flow rate was increased to 2,000 cc/min, to transfer the catalyst to fluidization region (8).

After the fluidization region (8) became stable, benzene previously heated to 300° C. was introduced as a carbon source into the reactor through an inlet (2) at a flow rate of 300 cc/min. After 10 minutes, the introduction of the catalyst and the carbon source was stopped and the reaction was allowed to continue for 2 hours to produce carbon nano-structures in the fluidization region (8).

Step 2) Purification of Carbon Nano-Structures

After the reaction was terminated, the temperature of the fluidization region of the reactor (5) was lowered to 300° C., and then oxygen was introduced into the reactor through the inlet (2) at a flow rate of 300 cc/min, to oxidize amorphous carbon impurities of the carbon nano-structures synthesized in Step 1), and then the flow rate of the oxygen gas was reduced to maintain the fluidized region of the carbon nano-structures to be stable. After the oxidization was completed, the introduction of oxygen was stopped, nitrogen was bubbled through a 50% aqueous nitric acid solution and introduced into reactor (5) through inlet (2) to etch the carbon nano-structures for 1 hour, while the temperature of inlet (2) was maintained at 150° C. After the completion of the etching process for the removal of impurities in the carbon nano-structures, the reactor was purged for 30 minutes using nitrogen to discharge oxygen completely through outlet (12).

Step 3) Surface-Treatment of Carbon Nano-Structures

Subsequently, nitrogen was bubbled through a 50% tetraethyl orthosilicate (TEOS) aqueous solution, a secondary surface-treating agent and introduced to the fluidized carbon nano-structures having hydroxyl and nitro groups obtained in Step 2) for 30 minutes though inlet (2). The introduction of the TEOS solution was stopped, and the reactor temperature was gradually raised to 600° C. at a rate of 10° C./min and maintained at 600° C. for 1 hour. Finally, the flow rate of the carrier gas introduced through inlet (1) was increased by 1.5 times to recover the purified and surface-treated carbon nano-structures at recovery part (11) and also to collect any aggregates, amorphous carbons and unpurified carbon nano-structures at recovery part (9), which were to be recycled to reactor (5). The carrier gas was discharged through outlet (12).

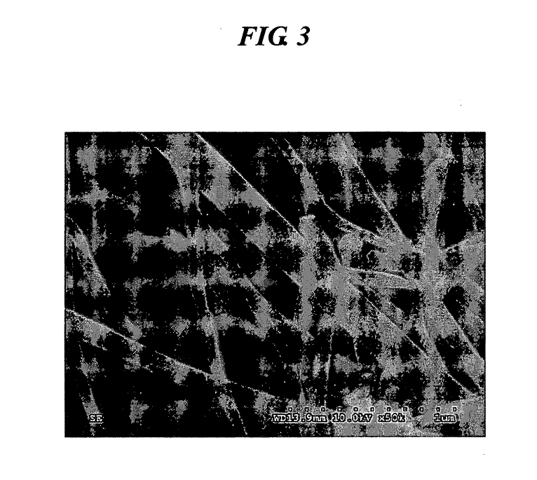

The purified and surface-treated carbon nano-structures thus obtained were analyzed with a scanning electronic microscope. The result in FIG. 3 shows that carbon nano-structures having a thickness of 0.1 to 0.3 μm are uniformly surface-treated with silica.

### EXAMPLE 2

### In Situ Purification and Surface-Treatment of Carbon Nano-Structures Using Fluidization

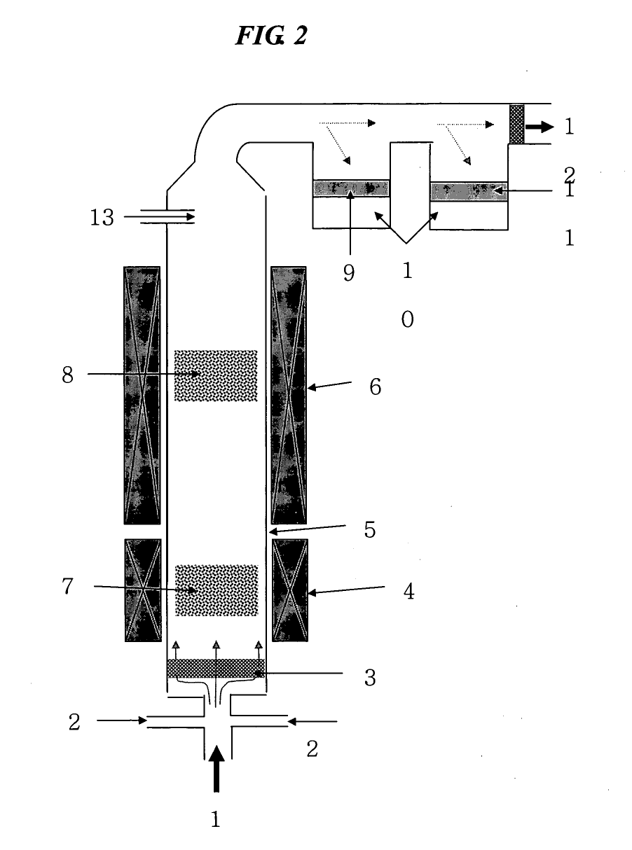

Carbon nano-structures synthesized with a conventional arc method were purified and in situ surface-treated, using the apparatus shown in FIG. 2, as follows:

Step 1) Purification of Carbon Nano-Structures

A He carrier gas was introduced into quartz reactor (5) through inlet (1) equipped with ceramic filter (3) at a flow rate of 2,000 cc/min. After the carrier gas flow was stabilized, 30 g of crude carbon nano-structures previously pulverized with a mill was introduced into the reactor (5) through inlet (13), to form a fluidized bed (8) of the carbon nano-structures.

After the temperature of the fluidized region (8) of the reactor (5) was raised to 300° C., oxygen was introduced into the reactor (5) through an inlet (2) at a flow rate of 100 cc/min, to oxidize amorphous carbon impurities of the carbon nano-structures, and then the flow rate of the oxygen gas was reduced to stabilize the fluidized region of the carbon nano-structures. After the oxidization was completed, the introduction of oxygen was stopped and nitrogen was introduced to purge the reactor for 30 minutes.

Step 2) Surface-Treatment of Carbon Nano-Structures

Subsequently, the temperature at the inside of the reactor (5) was controlled to 50 ⁰ c and gaseous fluorine was introduced to the reactor (5) was introduced at a flow rate of 100 cc/min to contact the fluidized carbon nano-structures having hydroxyl groups, obtained in Step 1), for 30 minutes. The introduction of gaseous fluorine was stopped and the reactor was purged with nitrogen. The reactor was heated to 600° C. to remove fluorine groups remaining on the nano-structures. Finally, nitrogen carrier gas flow rate was increased by 1.5 times to recover the purified and surface-treated carbon nano-structures at recovery part (11) and also to collect any aggregates, amorphous carbons and unpurified carbon nano-structures, which were to be recycled to the reactor (5), at recovery part (9).

The purified and surface-treated carbon nano-structures thus obtained were dispersed in water containing carboxymethyl cellulose (CMC) in an amount of 0.01 wt % based on the nano-structures, and its dispersability was determined. As a control, the crude carbon nano-structures used as a starting material were dispersed in water containing sodium dodecylbenzene sulfonate (SDS) in an amount of 0.01 wt % based on the nano-structures, and its dispersion degree was determined.

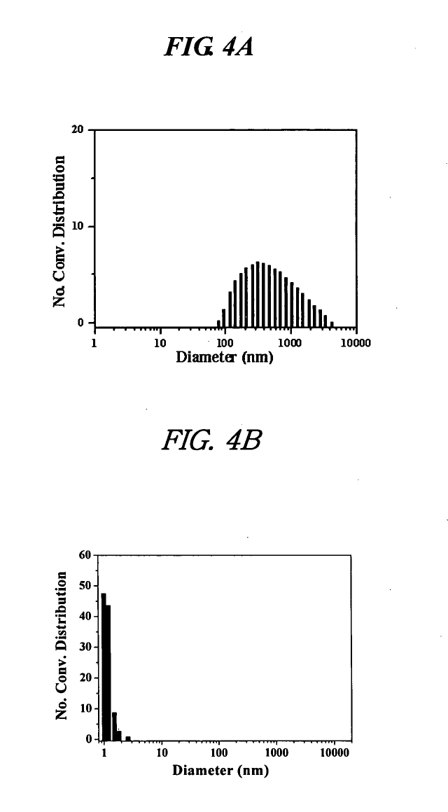

The results are shown in FIGS. 4A and 4B. From comparison of FIG. 4A and FIG. 4B, it can be seen that the carbon nano-structures treated according to the present invention are dispersed within a uniform size range of 1 to 4 nm, whereas the crude carbon nano-structures are dispersed within a wide particle size range of 100 to 5,000 nm.

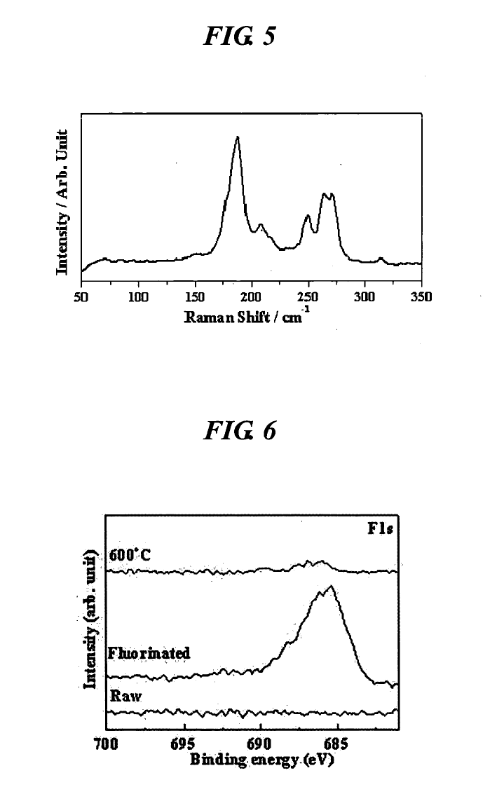

FIG. 5 shows Raman spectra of the carbon nano-structures purified as above. The peaks at 185, 210, 250 and 265 cm⁻¹ suggest that the materials purified according to the present invention still maintain the characteristics of the carbon nano-structures.

Further, X-ray photoelectron spectra of the nano-structures before and after the treatment with fluorine and after the heat-treatment (FIG. 6) shows that the fluorine peak at 686 eV disappears after the heat-treatment.

### EXAMPLE 3

### Purification of Carbon Nano-Structures by Simultaneous Oxidizing and Etching Processes

The carbon nano-structures synthesized in Step 1) of Example 1 were purified by simultaneously conducting the oxidizing and etching processes, as follows:

After the synthesis of the carbon nano-structures was terminated, the temperature of the fluidization region (8) of the reactor (5) was controlled to 450° C., and then 7:3 mixed gas of nitrogen and oxygen was bubbled through a 30% aqueous HCl solution and introduced at a flow rate of 100 cc/min into the reactor through inlet (2). The reactor was purged for 30 minutes with nitrogen. Since the oxidization reaction rapidly proceeds than the etching reaction, the two reactions did not interference with each other, and thus, it took a shorter (about a half) time than the purification step of Example 1.

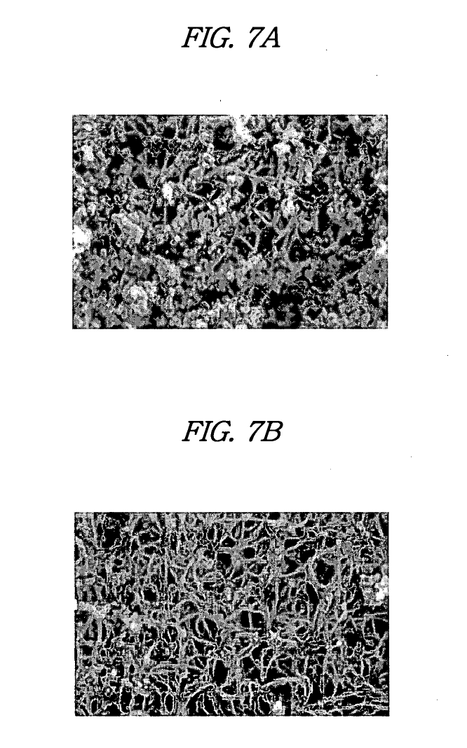

FIGS. 7A and 7B are scanning electronic microscopic photographs of carbon nano-structures before and after the purification according to Example 3, showing that the carbon nano-structures are effectively purified.

### EXAMPLE 4

### Purification of Carbon Nano-Structures Using Microwave Plasma

The carbon nano-structures synthesized in Step 1) of Example 1 was purified using a plasma generated by microwave, as follows.

After the synthesis of the carbon nano-structures was terminated, the flow rate of the carrier gas introduced through inlet (1) was controlled to 200 cc/min and a microwave-plasma was generated in the fluidized carbon nano-structure region (8). Oxygen was introduced at a flow rate of 100 cc/min to reactor (5) through inlet (2) to contact with the carbon nano-structures for 10 minutes. After the introduction of oxygen was stopped, argon was bubbled through a 30% aqueous nitric acid solution and introduced into the reactor through inlet (2) for 30 minutes at a flow rate of 100 cc/min. The reactor was purged with nitrogen for 30 minutes.

### EXAMPLE 5

### In situ Purification and Reinforcement of Carbon Nano-Structures

Crude carbon nano-structures synthesized with a conventional CVD method were purified and in situ continuously used in the production of a reinforced composite, using a fluidization method in the apparatus shown in FIG. 2, as follows.

A He carrier gas was introduced into quartz reactor (5) through inlet (1) equipped with ceramic filter (3) at a flow rate of 2,000 cc/min. After the carrier gas flow became stable, 10 g of the crude carbon nano-structures was introduced into the reactor (5) through inlet (13) to form a fluidized bed (8) of carbon nano-structures.

Subsequently, a 50% aqueous nitric acid solution, which was previously heat-treated at 80° C. for 5 hours, was heat treated at 170° C. to generate a vapor containing about 10% active oxygen, and introduced with a carrier gas into reactor (5) through inlet (2) at a flow rate of 2,500 cc/min, to be reacted with the carbon nano-structures at 400° C. to produce carbon nano-structures having nitro groups on the surface.

The flow rate of the carrier gas was increased to move the resulting carbon nano-structures toward outlet (12) to be immersed in a stirred polypyrrole polymer solution for producing a composite placed in port (10). A polymer composite containing the carbon nano-structures was obtained in port (10) whereas the carrier gas was vented off through outlet (12).

### EXAMPLE 6

### In situ Synthesis and Surface-Treatment of Carbon Nano-Structures

The carbon nano-structures synthesized in Step 1) of Example 1 was in situ surface-treated without purification, as follows.

After the synthesis of the carbon nano-structures was terminated, the temperature of the fluidized region (8) of reactor (5) was increased to 500° C., an Ar carrier gas was bubbled through a 5% tetrachlorosilane solution in anhydrous ethanol at room temperature and introduced into reactor (5) through inlet (2) for 30 minutes at a flow rate of 2,500 cc/min. After the introduction of the silane was stopped, the temperature of the fluidized region was gradually raised to 600° C. at a rate of 10° C./min and maintained at 600° C. for 1 hour, to obtain surface-treated carbon nano-structures with silane functional groups.

While the invention has been described with respect to the above specific examples, it should be recognized that various modifications and changes may be made to the invention by those skilled in the art which also fall within the scope of the invention as defined by the appended claims.

What is claimed is:

1. A method for treating a carbon nano-structure, which comprises:
(A) fluidizing the carbon nano-structure in a reactor using a carrier gas introduced into the reactor; and
(B) separately introducing a reactive gas in the reactor to contact the fluidized carbon nano-structure.

2. The method according to claim 1, wherein the carrier gas is selected from the group consisting of helium (He), argon (Ar), nitrogen (N₂), and a mixture thereof.

3. The method according to claim 1, wherein the carrier gas and the reactive gas are each independently introduced in the form of a up flow or a down flow.

4. The method according to claim 1, wherein the carbon nano-structure is synthesized by reacting a carbon source and a catalyst in a fluidized region of a reactor formed using a carrier gas.

5. The method according to claim 4, wherein the catalyst is employed together with an etching gas selected from ammonia and hydrogen.

6. The method according to claim 4, wherein the carbon nano-structure synthesized in the fluidized region is successively treated with a reactive gas in a fluidized region.

7. The method according to claim 6, wherein the synthesis and the treatment of the carbon nano-structure are conducted in a single reactor or in different reactors.

8. The method according to claim 1, wherein the reactive gas is a purifying gas or a surface-treating gas, or a combination thereof.

9. The method according to claim 8, wherein the purifying gas is an oxidative gas, an acidic gas or a combination thereof.

10. The method according to claim 9, wherein the oxidative gas is selected from the group consisting of air, oxygen, carbon dioxide, hydrogen peroxide, and a mixture thereof.

11. The method according to claim 9, wherein the acidic gas is selected from the group consisting of hydrochloric acid, nitric acid, fluoric acid, sulfuric acid, and a mixture thereof.

12. The method according to claim 9, wherein the oxidative gas and the acidic gas are employed either simultaneously or successively in any order.

13. The method according to claim 8, wherein the reactive gas is the purifying gas, and the carbon nano-structure treated with the purifying gas is further heat-treated.

14. The method according to claim 8, wherein the surface-treating gas is a preliminary surface-treating agent selected from the group consisting of ozone, nitrogen oxides, ammonia, hydrogen cyanide, sulfur oxides, chlorine, carbon dioxide, hydrochloric acid, nitric acid, fluoric acid, phosphoric acid, sulfuric acid, hydrogen peroxide, potassium permanganate, chlorine dioxide, potassium iodate, pyridine, hydrogen sulfide, nitrating agents, sulfonating agents and mixtures thereof.

15. The method according to claim 14, wherein the preliminary surface-treating agent generates at least one functional group selected from nitro (—NO₂), sulfone (—SO₃H), aldehyde (—CHO), carboxyl (—COOH), carbonyl (>CO), ether (—O—), hydroxyl (—OH), cyano (—CN), thiol (—SH), and phosphine (≡P), on the surface of the carbon nano-structure.

16. The method according to claim 8, wherein the surface-treating gas is a secondary surface-treating agent selected from the group consisting of silane-, titane-, borone-, and aluminium-based alkoxides and organocompounds; metal chlorides, nitrates, acetates or carbonates; coupling agents; vaporized metals; fluorinating gases; silating gases; phosphines; drug precursors; and mixtures thereof.

17. The method according to claim 8, wherein the surface-treating gas is a combination of a preliminary surface-treating agent with a secondary surface-treating agent, successively employed in two steps, the preliminary surface-treating agent being selected from the group consisting of ozone, nitrogen oxides, ammonia, hydrogen cyanide, sulfur oxides, chlorine, carbon dioxide, hydrochloric acid, nitric acid, fluoric acid, phosphoric acid, sulfuric acid, hydrogen peroxide, potassium permanganate, chlorine dioxide, potassium iodide, pyridine, hydrogen sulfide, nitrating agents, sulfonating agents and mixtures thereof, and the secondary surface-treating agent being selected from the group consisting of silane-, titane-, borone-, and aluminium-based alkoxides and organocompounds; metal chlorides, nitrates, acetates or carbonates; coupling agents; vaporized metals; fluorinating gases; silating gases; phosphines; drug precursors; and mixtures thereof.

18. The method according to claim 8, wherein the purifying gas and the surface-treating gas are employed in combination, and the treatment using them are conducted in a single reactor or in different reactors.
